(19) United States
(12) Patent Application Publication
(10) Pub. No.: US 2010/0288543 A1
(43) Pub. Date: Nov. 18, 2010

(54) CONDUCTING LINES, NANOPARTICLES, INKS, AND PATTERNING

(75) Inventors: Sheng-Chun Hung, Chicago, IL (US); Omkar Nafday, Tallahassee, FL (US); Jason R. Haaheim, Chicago, IL (US)

Correspondence Address: FOLEY AND LARDNER LLP;SUITE 500, 3000 K STREET NW, WASHINGTON, DC, 20007, US

(73) Assignee: NanoInk, Inc.

(21) Appl. No.: 12/759,572

(22) Filed: Apr. 13, 2010

Related U.S. Application Data
(60) Provisional application No. 61/169,254, filed on Apr. 14, 2009.

(51) Int. Cl. H05K 1/09; H05K 3/12; B32B 3/10

(52) U.S. Cl. 174/257; 427/98.4; 428/195.1

(57) ABSTRACT

Patterning and direct writing of nanoparticle inks formulated to provide conductive lines upon annealing. Patterning methods include stamp and tip based methods including microcontact printing and DPN printing. Ink viscosity, metal content, and density can be controlled to provide good results. Low temperature of annealing can be used to generate volume resistivities comparable to bulk resistivity. Long lines can be drawn. Addressable patterning can be achieved.

### RELATED APPLICATION

This application claims priority to U.S. Provisional Application Ser. No. 61/169,254, filed Apr. 14, 2009, which is incorporated herein by reference in its entirety.

### BACKGROUND

Small, thin conductive lines are an important aspect of modern technology including the electronics industry. Metallic lines are particularly important. A need exists to find better ways to prepare and characterize small, thin conductive lines, including lines at both the micron and nanometer scales. In many cases, however, it is difficult to achieve desired combinations of properties, including, for example, the ability for an ink to be both (i) processable and capable of being patterned, coupled with (ii) providing good, final properties after patterning and processing. Other needs exist in creating lines which are long and have high aspect ratios, which have sub-micron line widths, which are continuous and show high conductivity, which can be prepared by direct write methods, and/or which possess the ability to be addressable.

### SUMMARY

Provided herein are methods of making, methods of using, compositions including ink compositions, and structures and devices.

One embodiment provides a method comprising: providing at least one tip, providing at least one substrate, disposing at least one nanoparticle ink on the tip, wherein the ink comprises at least metallic nanoparticles and at least one solvent carrier and has a viscosity of at least 2,500 cps, moving the tip and substrate closer to each other such that at least some of the nanoparticle ink is deposited from the tip to the substrate.

Another embodiment provides a method comprising: providing at least one tip or stamp, providing at least one substrate, disposing at least one nanoparticle ink on the tip or stamp, wherein the ink comprises a paste comprising at least metallic nanoparticles and at least one solvent carrier, moving the tip or stamp and the substrate closer to each other such that at least some of the nanoparticle ink is deposited from the tip or stamp to the substrate.

Another embodiment provides a method comprising: providing at least one tip, providing at least one substrate, disposing at least one nanoparticle ink on the tip, moving the tip and substrate closer to each other such that at least some of the nanoparticle ink is deposited from the tip to the substrate, wherein the ink is formulated to provide continuous lines with resistivity of less than about 1.1×10⁻⁵ ohm-cm.

Another embodiment provides a method comprising: providing at least one substrate, directly writing at least one nanoparticle ink on the substrate, wherein the ink is formulated to provide continuous lines with resistivity of less than about 1.1×10⁻⁵ ohm-cm.

Another embodiment provides a method comprising: providing at least one tip, providing at least one substrate, disposing at least one nanoparticle ink on the tip, wherein the ink comprises at least metallic nanoparticles and at least one solvent carrier and has content of nanoparticles of at least 45% by weight, moving the tip and substrate closer to each other such that at least some of the nanoparticle ink is deposited from the tip to the substrate.

Another embodiment provides a method comprising drawing a continuous metallic line with an aspect ratio of at least 25 from an ink composition comprising metallic nanoparticles, wherein the line upon annealing shows a resistivity of less than about 1.1×10⁻⁵ ohm-cm.

Another embodiment provides a method comprising: (i) providing a tip with a nanoparticle ink disposed thereon; (ii) moving the tip closer to a first location on a substrate such that at least some of the ink composition is deposited from the tip to the first location on the substrate; (iii) moving the tip away from the substrate; and (iv) moving the tip closer to a second location on the substrate such that at least some of the remaining ink is deposited from the tip to the second location on the substrate to form a pattern.

Another embodiment provides a method comprising: (i) providing at least a first and a second electrode; and (ii) depositing at least one nanoparticle ink from a tip onto a first portion of the first and a second portion of the second electrodes so as to provide after annealing the ink a continuous line in electrical contact with both the first and second portion.

Additional embodiments include structures produced by these methods including conductive lines that have a lateral width of less than about 100 microns, or less than about 10 microns, or less than about 1 micron, or less than about 500 nm, or less than about 100 nm. In addition, conductive, continuous lines can be prepared which are at least five microns long, or at least 40 microns long.

At least one advantage in at least one embodiment is high conductivity lines.

At least one more advantage in at least one embodiment is consistent writing.

At least one more advantage in at least one embodiment is continuous, conductive lines.

At least one more advantage in at least one embodiment is small, narrow conductive lines including sub-micron lines.

At least one more advantage in at least one embodiment is the ability to avoid extensive modification of substrate.

At least one more advantage in at least one embodiment is ability to prepare high aspect ratio lines.

At least one advantage in at least one embodiment is direct writing.

At least one advantage in at least one embodiment is addressability.

At least one advantage in at least one embodiment is better tenability for a particular application.

At least one additional advantage includes measurable topography on the order of hundreds of nm. This can provide additional stability and better, more reproducible conductivity data. Topography helps to verify that what is written is what is desired to be written.

Provided herein also is at least one embodiment comprising the first demonstration of relatively reproducible sub-μm, sub-50-μΩ-cm Dip Pen Nanolithography® (DPN®)-generated conductive traces. Other embodiments comprise an article prepared by methods comprising the methods of any of the method claims described herein. The article can be a device, such as an electronic device. In an alternative embodiment, an article is described, the article comprising a continuous line comprising annealed nanoparticles, wherein the line has a resistivity of less than about 1.1×10⁻⁵ ohm-cm and a width of less than 1 micron. In another embodiment, the line has a resistivity of less than 50×10⁻⁶ ohm-cm.

In one embodiment, a method of bleeding of excess ink before patterning is described, the method comprising: (i) providing a tip with a nanoparticle ink disposed thereon; (ii) moving the tip closer to a first location on a substrate such that at least some of the ink composition is deposited from the tip to the first location on the substrate; (iii) moving the tip away from the substrate; and (iv) moving the tip closer to a second location on the substrate such that at least some of the remaining ink is deposited from the tip to the second location on the substrate to form a pattern. In one embodiment, the steps (ii) and (iii) can be repeated before step (iv) until the dots created as a result of each successive bleeding have comparable size.

An alternative embodiment describes a method of creating a continuous line, electrically connecting two electrodes, the method comprising: (i) providing at least a first and a second electrode; and (ii) depositing at least one nanoparticle ink from a tip onto a first portion of the first and a second portion of the second electrodes so as to provide after annealing the ink a continuous line in electrical contact with both the first and second portion. The same process can be carried out with a stamp instead of a tip. Alternatively, the process can be carried out via polymer pen lithography as described above. For example, the process can be carried out via a polymer pen lithography embodiment in which no cantilever is employed.

### BRIEF DESCRIPTION OF FIGURES

FIG. 1 shows SEM image of a line drawn across a gold electrode.

FIG. 2 shows SEM image of lines drawn across multiple gold electrodes.

FIG. 3 shows SEM image of a line drawn across a gold electrode.

FIG. 4 shows AFM analysis of a silver line.

FIG. 5 shows AFM height analysis of a silver line.

FIG. 6 shows the results of I-V testing for a silver line.

FIG. 7 shows a c-AFM substrate which was subjected to deposition to create silver nanoparticle lines (mm unit).

FIG. 8 shows a c-AFM substrate which was subjected to deposition to create silver nanoparticle lines (micron unit).

FIG. 9 illustrates silver lines which are not continuous.

FIGS. 10A-10D illustrate silver lines which are not continuous with writing speed variation for four different writing speeds.

FIGS. 11A-11D illustrate silver lines which are not continuous with writing speed variation for four different writing speeds.

FIGS. 12A-12C illustrate silver lines which are not continuous with writing speed variation for four different writing speeds.

FIGS. 13(a)-(b) provide a schematic representation of directly depositing AgNP ink solution onto a generic substrate via DPN. (a): Zoomed in perspective showing the necessarily high concentration of silver nanoparticles and the flow of AgNP ink via a viscous paste meniscus that envelops the tip. (b): Zoomed out perspective showing the creation of a continuous silver trace by moving the tip across the surface. A small ink “reservoir” forms behind the tip on the underside of the cantilever, and feeds the meniscus that envelops the tip. For scale, real-world tip/cantilever dimensions are: cantilever length≈200 μm, cantilever width≈50 μm, cantilever thickness≈0.5 μm, tip height (base-to-apex)≈4 μm, tip end-radius ≈15 nm.

FIGS. 14(a)-(c) show characterization of generated continuous lines across electrodes. (a): SEM image of a DPN-patterned conductive trace across four electrodes, with several sub-μm line width inter-electrode traces shown. (Note: the AgNP ink spreads to broader features on the gold traces due to gold's higher contact angle.) The inset black zoombox indicates the region shown in (a), where the 500 nm wide continuous trace spans the 4.5 μm wide gap between electrodes, and where the ink is clearly able to maintain continuity up and over the ˜25 nm electrode step height. (c): I-V curve data—where several hundred data points appear as a continuous line—verifies trace conductivity and yields a trace resistance R=108.5Ω, with a corresponding resistivity ρ=10.0 μΩ-cm. (Note: for bulk silver, ρ=1.63 μΩ-cm.) Resistivity calculations incorporate trace height data shown in FIG. 15(c), (e).

FIGS. 15(a)-(e) show line patterning results across 10 separate experiments attesting to the patterning control repeatability of the results shown in FIG. 14. (a): Optical microscopy image of consistent line profiles generated on the same substrate SiO2 from 10 separately inked SiN tips. The bleeding dots are shown just below the start of each line trace, drawn from bottom to top. (b)(d): TM-AFM height image of the lines shown in inset boxes [1] and [2], and (c)(e): their corresponding line trace profiles showing line thicknesses from 120-400 nm. (f): Plot examining the relationship between the size of the bleeding dot and the resulting line length; a roughly linear correlation supports the intuitive notion that higher ink loading results in a larger initial bleeding dot, and that a higher-loaded cantilever will subsequently result in a longer line trace. (See FIG. 18 for bleeding dot area and line length measurements.)

FIGS. 16(a)-(c) provided AgNP conductive trace electrical performance data gathered from across 11 separate sets of electrodes, reinforcing the highly repeatable electrical characterization results shown in FIG. 14. (a): SEM image of an unpatterned C-AFM substrate, showing multiple sets of Au electrodes on an SiO2 substrate. A schematic line shows the intended location of a DPN-patterned AgNP conductive trace, along with arrow indications for placing the 4-point probe measurement needles to generate the validating I-V curves. (b): I-V curve data verify the conductivity of all patterned traces and show a range of trace resistance from R=0.23-2.10Ω. (c): Corresponding resistivity values range from ρ=0.8-86.0 μΩ-cm are shown in the inset plot. The average of 28.80±28.45 μΩ-cm compares favorably with the ink manufacturer's specification of 6.0μΩ-cm (and bulk silver ρ=1.63μΩ-cm) when considering that the manufacturer measured conductivity across a large-area, multi-μm thick pattern, as opposed to our sub-μm heights and widths. (Resistivity calculations assume trace height data comparable to those shown in FIG. 15(c), (e). SEM images of the 11 traces are found in supporting information FIG. 19.)

FIGS. 17(a)-(e) show results that demonstrate the versatility and substrate generality of the DPN conductive trace methodology: (a): optical microscope image of AgNP lines on Kapton tape; (b): TM-AFM height image showing continuous lines of the zoom-box area from (a); (c): topographic line trace profiles of (b). (d): Optical microscope image showing continuous AgNP lines on mica, with (e): a TM-AFM image showing the zoom-box area from (d), and (f) corresponding topographic profiles.

FIGS. 18 (a)-(d) shows SEM images of representative AgNP traces within electrode gaps, consisting of intentionally varied bleeding dot areas and line lengths in order to examine the relationship seen in FIG. 15(f). Dot and line measurements are shown in inset, and were subsequently incorporated into the plot shown in FIG. 15(f).

FIG. 19 (a)-(d) provides combined SEM images and I-V curves showing the measurements on the multiple samples whose combined plots are shown in FIGS. 16(b) and 16(c).

### DETAILED DESCRIPTION

### Introduction

All references cited herein are incorporated by reference in their entirety.

Patterning of conductive lines and nanoparticles is described in, for example, US Patent Publication No. 2005/0235869 (NanoInk, Skokie, Ill.); and PCT/US2008/079893 (NanoInk, Skokie, Ill.).

Patterning nanoparticle inks by DPN® printing is described in Wang et al., Applied Physics Letters, 93, 143105 (2008).

Deposition of nanoparticle inks through a nozzle is described in Ahn et al., Science, 323, 1590-1593, Mar. 20, 2009.

Nanoparticles inks are described in Li et al., Adv. Mater., 2003, 15, No. 19, 1639-1643; and in Wang et al., ACSNANO, 2, 10, 2135-2142.

Metallic nanoparticle (NP) inks offer a versatile, low-cost option to create conductive traces between two electrodes. This ability to “nano-solder” two junctions—or probe disparate elements of pre-existing microcircuitry—lends itself to applications in printed circuit fabrication and flexible electronics such as, for example, failure analysis of complex microcircuitry, gas sensing, and solar-cell metallization. NP based inks can comprise solutions of silver (Ag), gold (Au), or copper (Cu), which can be annealed/cured at relatively low temperatures (e.g., about 100-300° C.), and which exhibit low resistivity (<50-μΩ-cm) after deposition and curing. This simple two step metallization process is especially suitable for low cost electronics fabrication. However, in the general realm of conductive trace fabrication it is challenging both to achieve precise direct-deposition at specific user-defined sites and to reliably control the dimensions of these metal traces in the 0.5-50.0 μm range.

Many different approaches already exist to create microscale conductive traces, including drop-on-demand (DOD) ink-jet printing, surfactant assisted multiphoton-induced metal reduction, laser induced NP growth for metal patterning, reduction of metal ions in solution, functionalized block copolymer patterning, vapor reduction, screen-printing, direct imprinting, and microcontact printing (μ-CP).^{1a-1} However, these techniques all have some drawbacks. For example, DOD ink jet printing suffers from ink clogs that form in the nozzle; additionally, the minimum feature width (30-60 μm) is limited by the minimum nozzle diameter (1-10 μm), and the ink rheology is subsequently constrained by the nozzle dimensions. Similarly, the resolution of μ-CP is constrained by the limitations of optical lithography, and defects are frequently observed due to issues of stamp/substrate gap and printing force. Cao et al. demonstrated 180 nm line width conductive AgNP structures;^{1e} however, their approach added extensive energy via lasers and photo-reducing chemicals, involved considerable surface modification, and did not directly-deposit the conductive trace. Other approaches such as AgNP paste screen printing involve the use of a mesh screen to define the shape and size of the desired electrode and stencils to block certain regions of the screen. However, this approach needs multiple screens for different electrodes, is neither direct-write nor sub-μm, and was limited to patterning on quartz substrates in the cited work.^{1j} More closely related, Wang et al. demonstrated highly-controlled deposition of gold nanoparticle (AuNP) sub-μm lines, but their AuNP traces were neither continuous nor conductive.^{1m} In order to truly explore nanoelectronic phenomena—and expand this frontier by applying metallic sub-μm nanoparticle-ink-based conductive traces to areas such as printed circuitry, photonics, and chemical/biosensors—other deposition methods which are versatile and non-energy-intensive need to be implemented. Additionally, to ensure complementarity with existing electronic fabrication methods, desirable nanoparticle-based ink deposition methods should avoid extensive modification of the surface.

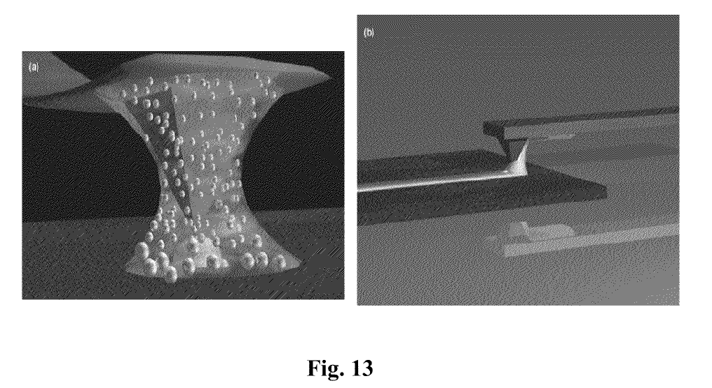

Dip Pen Nano lithography® (DPN®) is a promising candidate for achieving these objectives. A schematic of the approach is shown in FIG. 13. Because of its basis as a scanning probe technique, DPN has the unique ability to direct-write traces and register them to existing surface features with nanoscale precision.^{2a-b} This capability alone differentiates DPN as the singular approach for sub-nm decoration of existing microstructures, site-specific device element functionalization, or cosmetic electrical touch-up of microelectronic elements. Furthermore, DPN is low cost, operates in ambient environment, and does not require physical or chemical modifications of the pre-existing substrate.

### Patterning

Patterning and printing methods are known in the art including, for example, microcontact printing and other soft lithography methods, nanoimprint lithography, scanning probe methods, DPN printing, as well as printing methods like ink jet printing, flexography, off-set, screen, gravure printing, and the like. In some of these methods, ink material is transferred from a sharp tip or stamp to a substrate. Direct writing can be achieved to draw a pattern.

If a stamp is used, the stamp can be a soft, elastomeric stamp made of silicone polymer like polydimethylsiloxane and used for deposition. In one alternative embodiment related to using a elastomeric stamp, a polymer tip, such as a soft elastomer tip, is used for patterning. Patterning with a elastomeric tip can be sometimes referred to as “polymer pen lithography.” In one embodiment, polymeric pen lithography can be carried without a cantilever. Polymer pen lithography can also be carried out with a plurality of tips at the same time.

In one embodiment, a tipless cantilever can be used for deposition.

In one embodiment, patterning is carried out without a nozzle.

In one embodiment, patterning is carried out without a stamp.

The substrate can be a variety of solids including metals, glasses, semiconductors, and polymers including, for example, silicon, silicon dioxide, metallic electrodes, and gold electrodes. The substrate can be insulative, conducting, or semiconducting. The substrate can be a composite and present different materials to the surface such as both a semiconductor or a conductor.

The substrate can comprise metallic lines or electrodes. Examples are described in U.S. Pat. No. 7,199,305 (Protosubstrates).

Substrates can present hydrophobic or hydrophilic surfaces. In one embodiment, the surface provides a hydrophilicity such that water contact angle is about 15° to 35°, or 20° to 30°.

Scanning probe and DPN methods are known in the art. See, for example, Scanning Probe Microscopies Beyond Imaging, Samori, Wiley, 2006.

### DPN Printing

DPN printing, including instrumentation, materials, and methods, is generally known in the art. See, for example, Haaheim et al., Ultramicroscopy, 103, 2005, 117-132. For practice of the various embodiments described herein, lithography, microlithography, and nanolithography instruments, pen arrays, active pens, passive pens, inks, patterning compounds, kits, ink delivery, software, and accessories for direct-write printing and patterning can be obtained from NanoInk, Inc., Skokie, Ill. Software includes INKCAD and NSCRIPTOR softwares (NanoInk, Skokie, Ill.), providing user interfaces for lithography design and control. E-Chamber can be used for environmental control. Dip Pen Nanolithography®^{M} and DPN® are trademarks of NanoInk, Inc.

The following patents and co-pending applications related to direct-write printing with use of cantilevers, tips, and patterning compounds are hereby incorporated by reference in their entirety and can be used in the practice of the various embodiments described herein, including inks, patterning compounds, software, ink delivery devices, and the like:

U.S. Pat. No. 6,635,311 to Mirkin et al., which describes fundamental aspects of DPN printing including inks, tips, substrates, and other instrumentation parameters and patterning methods;

U.S. Pat. No. 6,827,979 to Mirkin et al., which further describes fundamental aspects of DPN printing including software control, etching procedures, nanoplotters, and complex and combinatorial array formation.

U.S. patent publication number 2002/0122873 A1 published Sep. 5, 2002 (“Nanolithography Methods and Products Produced Therefor and Produced Thereby”), which describes aperture embodiments and driving force embodiments of DPN printing.

U.S. regular patent application Ser. No. 10/366,717 to Eby et al., filed Feb. 14, 2003 (“Methods and Apparatus for Aligning Patterns on a Substrate”), which describes alignment methods for DPN printing (published Oct. 2, 2003 as 2003/0185967).

U.S. regular patent application Ser. No. 10/375,060 to Dupeyrat et al., filed Feb. 28, 2003 (“Nanolithographic Calibration Methods”), which describes calibration methods for DPN printing.

U.S. Patent Publication 2003/0068446, published Apr. 10, 2003 to Mirkin et al. (“Protein and Peptide Nanoarrays”), which describes nanoarrays of proteins and peptides;

U.S. Regular patent application Ser. No. 10/307,515 filed Dec. 2, 2002 to Mirkin et a. (“Direct-Write Nanolithographic Deposition of Nucleic Acids from Nanoscopic Tips”), which describes nucleic acid patterning (PCT/US2002/038252 published Jun. 12, 2003).

U.S. Regular patent application Ser. No. 10/320,721 filed Dec. 17, 2002 to Mirkin et al. (“Patterning of Solid State Features by Direct-Write Nanolithographic Printing”), which describes reactive patterning and sol gel inks (now published Aug. 28, 2003 as 2003/0162004).

U.S. Pat. Nos. 6,642,129 and 6,867,443 to Liu et al. (“Parallel, Individually Addressible Probes for Nanolithography”), describing active pen arrays.

U.S. Patent Publication 2003/0007242, published Jan. 9, 2003 to Schwartz (“Enhanced Scanning Probe Microscope and Nanolithographic Methods Using Same”).

U.S. Patent Publication 2003/0005755, published Jan. 9, 2003 to Schwartz (“Enhanced Scanning Probe Microscope”).

U.S. patent application Ser. No. 10/637,641 filed Aug. 11, 2003, now published as 2004/0101469, describing catalyst nanostructures and carbon nanotube applications.

U.S. patent application Ser. No. 10/444,061 filed May 23, 2003, now published as 2004/0026681 published Feb. 12, 2004, and US patent publication 2004/0008330 published Jan. 15, 2004, describing printing of proteins and conducting polymers respectively.

U.S. patent application Ser. No. 10/647,430 filed Aug. 26, 2003, now U.S. Pat. No. 7,005,378, describing conductive materials as patterning compounds.

U.S. patent application Ser. No. 10/689,547 filed Oct. 21, 2003, now published as 2004/0175631 on Sep. 9, 2004, describing mask applications including photomask repair.

U.S. patent application Ser. No. 10/705,776 filed Nov. 12, 2003, now published as 2005/0035983 on Feb. 17, 2005, describing microfluidics and ink delivery, as well as inkwells.

U.S. patent application Ser. No. 10/788,414 filed Mar. 1, 2004, now published as 2005/0009206 on Jan. 13, 2005 describing printing of peptides and proteins.

U.S. patent application Ser. No. 10/893,543 filed Jul. 19, 2004, now published as 2005/0272885 on Dec. 8, 2005, describing ROMP methods and combinatorial arrays.

U.S. patent application Ser. No. 11/056,391 filed Feb. 14, 2005, now published as 2005/0255237 published on Nov. 17, 2005, describing stamp tip or polymer coated tip applications.

U.S. patent application Ser. No. 11/065,694 filed Feb. 25, 2005, now published as 2005/0235869 on Oct. 27, 2005, describing tipless cantilevers and flat panel display applications.

US Patent publication 2006/001,4001 published Jan. 19, 2006 describing etching of nanostructures made by DPN methods.

WO 2004/105046 to Liu & Mirkin published Dec. 2, 2004 describes scanning probes for contact printing

US Patent Publication 2007/0129321 to Mirkin describing virus arrays.

See also two dimensional nanoarrays described in, for example, US Patent Publication 2008/0105042 to Mirkin et al., filed Mar. 23, 2007, which is hereby incorporated by reference in its entirety. See, also, US Patent Publication 2008/0309688 to Haaheim et al.

Another patterning instrument is described in, for example, US Patent publication 2009/0023607 to Rozhok et al.

DPN methods are also described in Ginger et al., “The Evolution of Dip-Pen Nanolithography,” Angew. Chem. Int. Ed. 43, 30-45 (2004), including description of high-throughput parallel methods.

Direct write methods, including DPN printing and pattern transfer methods, are described in for example Direct-Write Technologies, Sensors, Electronics, and Integrated Power Sources, Pique and Chrisey (Eds) (2002).

Scanning probe microscopy is reviewed, for example, in Bottomley, Anal. Chem. 70, 425R-475R (1998). Also, scanning probe microscopes are known in the art including probe exchange mechanisms as described in, for example, U.S. Pat. No. 5,705,814 (Digital Instruments).

1-D or 2-D arrays can be used including arrays with large volumes of tips and cantilevers including, for example, at least 55,000, or at least 1,000,000, or at least 10,000,000. See, for example, US Patent Publication 2008/0105042 to Mirkin et al.

The tips can be hard tips like Si or silicon nitride or soft tips like polymeric tips.

The writing speed can be any suitable speed, depending on the application and the material used. For example, it can be between 0.1 microns/s and 100 microns/s, such as between 20 microns/s and 90 microns/s, such as between 40 microns/s and 80 microns/s.

### Ink Composition

The ink composition can comprise at least metallic nanoparticles and at least one solvent carrier. The ink composition can be a paste. Pastes are known in the art. Nanoparticles are known in the art. See, for example, Poole, Owens, Introduction to Nanotechnology, 2003 (Wiley); US Patent Publication No. 2008/0003363; Li et al., Adv. Mater., 2003, 15, No. 19, 1639-1643; and in Wang et al., ACSNANO, 2, 10, 2135-2142.

Solvent carriers are known in the art including both aqueous and non-aqueous-based carriers.

The ink composition can comprise formulation parameters which are adapted for good printing and good final properties. Examples of parameters include contact angle, inking of tips, tip speed versus size control, different sources of nanoparticle inks, and solvent selection. Solvent parameters also include drying rate, viscosity, ink polarity compared to tip and substrate polarity, and metal content.

The paste can have a viscosity that is adapted for patterning and tip-based deposition. For example, viscosity can be at least 2,500 cps, or at least 5,000 cps, or at least 6,000 cps, or at least 7,000 cps. The viscosity can be more than 1,500 cp at 10 s⁻¹ (25° C.).

The metallic nanoparticles can be any metal which can be adapted to be in a nanoparticle form such as, for example, silver, gold, copper, palladium, or platinum, and mixtures and alloys thereof.

Average particle diameter can be, for example, about 1 nm to about 100 nm, or about 2 nm to about 75 nm, or about 20 nm to about 50 nm.

The paste can have a density that is adapted for patterning and tip-based deposition. For example, density can be at least 2 g/cc, or at least 2.2 g/cc.

The paste can have a metal content that is adapted for patterning and tip-based deposition. For example, metal content can be at least 45% by weight, or at least 55% by weight, or at least 60% by wt., or at least 70% by weight, or at least 80% by weight.

Combinations of properties can be present. For example, the paste can have a viscosity which is at least 2,500 cps, a density of at least 2 g/cc, and a metal content of at least 45% by wt.

The solvent carrier system can be adapted for the substrate and tip. It can comprise water. The pH can be adapted for the application.

The ink composition can be substantially or totally free of glycerol.

The nanoparticles should be well-suspended in the solvent carrier and show long shelf life.

Inks can be obtained from InkTec, Anson-City, South Korea, including the PA Series for paste inks (PA-010, PA-020, PA-030).

The ink can have a contact angle on silicon wafer (HF cleaned) of 70°; on Teflon of 110°; on Silicon wafer without cleaning of 40-50°.

The ink can provide flexibility, high adhesiveness, and short term sintering.

The ink can be transparent electronic conductive ink and show transparency in the liquid phase.

The ink can comprise nanoparticles which do not need to or have the ability to chemisorb to or covalently bond to the substrate.

In some embodiments, the ink can be sufficiently viscous that it cannot be used with inkwells comprising microfluidic channels.

In one embodiment, the ink composition consists essentially of the solvent carrier and the nanoparticles.

In one embodiment, the ink composition is substantially free of polymeric materials.

In one embodiment, the composition is free of binder materials. In one embodiment, the composition is free of matrix materials.

In one embodiment, the ink solids are at least 75% by wt. metallic, or at least 85% by wt. metallic, or at least 95% by wt. metallic.

In one embodiment, the ink is substantially free of metal salts such as silver salts.

Stabilizers for nanoparticle inks are known in the art.

In one embodiment, the ink does not have to be sonicated or vortexed before use.

The ink color can be, for example, dark green.

The ink composition can be a first composition before it is applied to the tip, or it can be a second composition after it is applied to the tip, or it can be third composition after it is applied to the tip and dried, or a fourth composition after it is deposited on a substrate.

In some embodiments, the ink composition can consist essentially of the ingredients described and formulated herein. Ingredients which detract from the advantages described herein can be excluded or substantially excluded. For example, they can be limited to less than 1 wt. %, or less than 0.1 wt. %, or less than 0.01 wt. %.

### Method of Using Ink Composition

The tip and substrate can be moved closer to each other so that deposition of the ink or paste can occur. The tip can be held stationary or can be moved to form a line. The line can be straight or curved.

The tips can comprise inorganic materials like silicon or silicon nitride. In one embodiment, the tip is free of a coating such as an organic coating.

The tip can be moved at a rate of, for example, about 1 micron/second to about 200 microns/second, or about 1 micron/second to about 100 microns/second, or about 40 microns/second to about 80 microns per second.

The temperature and relative humidity during deposition can be controlled and adapted to achieve desired results. Closed or controlled environment can be used. The deposition can also be carried under ambient condition. An example of the am bient condition can be room temperature, such as 25° C., at a relative humidity of about 40-50%, such as 45%.

Conductive lines can be drawn across electrodes.

If desired, excess ink can be bled off before the patterning of desired structures. In one embodiment, this bleeding step is not executed.

High resolution writing with good alignment can be achieved. For example, in one embodiment, the line is deposited next to another feature, wherein the feature and the line are separated by a spacing, and the spacing is less than about five microns, ore less than about one micron, or less than about 500 nm, or less than about 250 nm. A lower separation distance can be, for example, 100 nm. Two metallic lines can be fabricated with this spatial separation. Alternatively, the line can be deposited over another feature. For example, the line can be deposited over a portion of another feature, such as substantially the entire feature.

The ink composition can be pre-baked (or pre-heated) before patterning to adjust the viscosity of the ink. Depending on the application and the material used, pre-baking can be carried out at any suitable temperature any suitable time. For example, it can be carried out at between about 20° C. and about 200° C., such as between about 40° C. and about 160° C., such as between about 80° C. and about 120° C. The pre-baking time can be, for example, less than or equal to about 20 minutes, such as less than or equal to about 15 minutes, such as less than or equal to about 10 minutes. Pre-baking can be carried out via a variety of techniques. For example, it can be carried out on a hot plate. Alternatively, it can be carried out on a heated tip, including an “active pen DPN,” and thermal DPN.

One distinguishable feature of the presently described method is that the transport of the ink onto the substrate need not rely on the formation of a water meniscus. For example, the deposition can be carried without substantially forming a water meniscus. Not to be bound by any theory, but this can be because the ink (e.g., metallic nanoparticle ink) is already in the liquid phase. One result is that experimental parameters of temperature and relative humidity can have minimal effect on the viscous paste meniscus or the resulting patterns.

### Annealing

Following DPN patterning, the substrate can be heated (or “baked”) at a higher temperature (such as at 150° C. via a hotplate) for a period of time (such as 10 minutes) to anneal or cure the ink solution and remove any excess solvent. The ink solution can be in a form a liquid solution or a highly viscous fluid, such as a paste.

The paste can be adapted for relatively low temperature annealing. For example, the deposited material can be annealed at 100° C. to about 200° C., or about 120° C. to about 170° C. The annealing time can be, for example, about 0.5 minutes to about 20 minutes, such as about 1 minute to about 10 minutes, such as about two minutes to about five minutes. Annealing can be carried out by any suitable devices, such as hot plate, radiation device, oven.

### Structures Formed and Characterization

A variety of shapes and lines can be formed. Dots or lines can be formed on substrates. Lines can be straight or curved. Complex geometrical shapes at high resolution can be prepared such as triangles, squares, circles, rectangles, grids, arrays, and the like.

The process can be repeated as needed at the same point on the substrate to increase the density of metal nanoparticles and/or increase line height. However, one embodiment is to do the deposition only once at a certain point or area on the substrate, including a point or area which is addressed and specified.

AFM and SEM can be used to characterize structures. In particular, structures after annealing can be characterized.

The line width of the line can be in the sub-micron range. In one embodiment, line width can be, for example, 10 nm to 2 microns, or 50 nm to 1 micron, or 100 nm to 750 nm, or 200 nm to 700 nm, or 300 nm to 600 nm, or 400 nm to 500 nm.

The height of the line can be, for example, about 100 nm to about 1 micron, or about 120 to 400 nm, or about 200 nm to about 750 nm, or about 250 nm to about 500 nm.

The length of the line can be, for example, at least five microns long, or at least 25 microns long, or at least 40 microns long, or at least 60 microns long, or at least 80 microns long, or at least 100 microns long, or at least 120 microns long, or at least 150 microns long.

Aspect ratio can be, for example, at least two, or at least five, or at least ten, or at least twenty, or at least fifty, or at least 100, or at least 200, or at least 300, or at least 400, or at least 500. An upper limit for aspect ratio can be, for example, 1,000.

Resistivity can be measured including volume resistivity. Resisitivity herein generally refers to electrical resistivity. Examples for the resistivity include less than 10⁻⁴ ohm-cm (“Ω-cm”), or less than 5×10⁻⁵ ohm-cm, or less than 3×10⁻⁵ ohm-cm, or less than 2×10⁻⁵ ohm-cm, or less than 10⁻⁵ ohm-cm, or less than 5×10⁻⁶ ohm-cm, or less than 3×10⁻⁶ ohm-cm, or less than 2×10⁻⁶ ohm-cm, or less than 10⁻⁶ ohm-cm. In one embodiment, the resistivity is less than 1.1×10⁻⁵ ohm-cm. In another embodiment, the resistivity is less than 50×10⁻⁶ ohm-cm.

### Bleeding Off Excess Ink

Depending on the application and the material used, occasionally ink composition in excess amount can be deposited onto the tip. In such a case, it can be desirable to remove the excess ink before commencing the patterning step.

In one embodiment, a method of bleeding off excess ink before patterning is described. The method comprises the following: (i) providing a tip with a nanoparticle ink disposed thereon; (ii) moving the tip closer to a first location on a substrate such that at least some of the ink composition is deposited from the tip to the first location on the substrate; (iii) moving the tip away from the substrate; and (iv) moving the tip closer to a second location on the substrate such that at least some of the remaining ink is deposited from the tip to the second location on the substrate to form a pattern. In one embodiment, the steps (ii) and (iii) can be repeated before step (iv) until the dots created as a result of each successive bleeding have comparable size. The first or second location can be on any suitable location on the respective first and second electrodes.

In particular, after initial touch down of the tip during pre-patterning bleeding, and depending on the amount of ink loading on the tip/cantilever, a pattern such as a dot would form as a result of the transfer of a small portion of the ink from the tip to the substrate. If the bleeding process includes repeated, successive transfers of the ink onto the substrate to create a series of the “bleeding dots,” the bleeding dots from a given tip will approach and maintain a consistent size.

The tip can be cleaned to remove contamination before the ink composition is disposed thereon. Any suitable cleaning method can be used. For example, the tip can be cleaned with oxygen plasma, with a solvent, or with an energy source, such as heat or radiation.

The presently described bleeding method has one advantage in that the force feedback is not needed. Not to be bound by any particular theory, force feedback is not needed for several reasons: this type of physisorbed DPN patterning is mostly force-independent, and the Z-distance needed to break contact from the AgNP ink meniscus is larger than the Z-range typically available during force feedback. Note that in one embodiment, after bleeding the patterning is carried out using the same Z-piezo actuator control (motor). Additionally, the large-range stage motors can be enabled to move the sample under the tip for creating lines longer than the 90 μm limit of the piezo scanner.

### Applications

Applications include, for example, printed electronics, RFID tag antennae, flexible circuits, smart card circuitry, smart labels, lead free solder, nano circuit repair, food preservation, or modifications thereof. Other applications include, for example, LCD, OLED, OTFT, FPCB, PCB, PDP, flexible displays, EMI shelter, sensors, bioarrays, antimicrobial disinfection, micro fuel cells, membrane switches, and solar cells.

The presently described direct-write methodology can provide site-specific deposition of metallic materials for use in applications such as circuit repair, sensor element functionalization, failure analysis, gas sensing, and printable electronics. The circuit repair can be carried out by creating an electrically conductive (and continuous) line across a plurality of electrodes. In one instance, some of the electrodes might have lost electrical contact with another. For example, in one embodiment wherein a plurality of electrodes are found. A nanoparticle based ink can be deposited from a tip or stamp onto the first and second electrodes such that the ink forms a line that is in electrical contact with a portion of the first and a portion of the second electrode. Alternatively, the ink can be deposited via polymer pen lithography as described above. The electrical contact can be formed by the ink immediately after the deposition onto the electrodes or can be formed after the ink is annealed to form a continuous conductive line.

Additional description is provided with use of the following working examples.

### NON-LIMITING WORKING EXAMPLES

### Working Example 1

A silver nanoparticle ink, Ink TEC-PA-010, was obtained from InkTec characterized by:

Viscosity: 7,000-7,500 cps (Brookfield DV-II+PRO (Spindle: 15, 200 rpm, at 25° C.)

Density: 2.2 g/cc (at 25° C.)

Metal content: 55±10% by wt. (TGA analysis)

Color: dark green (visual)

This ink is a hybrid nano silver paste. It can be printed by flat or rotary screen methods. Performance parameters include:

Curing temperature: 140 C×5 min (IR & circulating heat oven)

Printing layer thickness: 1-2 microns

Sheet Resistivity: 40-50 mohm/sq.

Volume Resistivity: under 6.0×10⁻⁶ ohm-cm

Adhesion (PET): Class 5B-4B (ASTM D3359 rating)

Substrates: PET, PI, PP, and the like

Hardness: 2H, pencil hardness

The ink was placed in a vial. The vial was hand shaken several to times to help avoid phase separation. A pipette was used to some ink on a silicon wafer which was wiped evenly.

Tips were mounted on the instrument used. A Si wafer was fixed with the silver nanoparticle inks on the chuck of the instrument. The tip was moved to approach the surface. When the tip was close, the piezo was applied to move the tip down to ink it onto the silver nanoparticle ink. A color change was observed because the tip was immersed in the ink, and the reflection changed. The tip was left immersed for 30 seconds. The tip was then raised from the surface comprising ink disposed on the tip.

The instrument used to pattern the ink included NSCRIPTOR™ and/or DPN5000™ (NanoInk, Skokie, Ill.).

The tips used to pattern the ink were A-Type and M-type silicon nitride tips. Both single tips and one dimensional arrays of tips were used.

The tips were cleaned with oxygen plasma for 30 seconds to make sure the tips are hydrophilic and not hydrophobic.

Closed environment was found useful to provide a more reproducible procedure, and closing off to airflow can reduce evaporation. Hence, in use of the ink for patterning, the chamber door of the patterning instrument was kept close. If the chamber door is closed, the ink an be used for the whole day. If the door is not closed, the ink will dry out in 2-3 hours.

The writing speed was 0.1 micron/second to 100 microns/second. The best writing speed was between about 40 microns/second and 80 microns/second. If writing speed was too slow, the line was short and discontinuous.

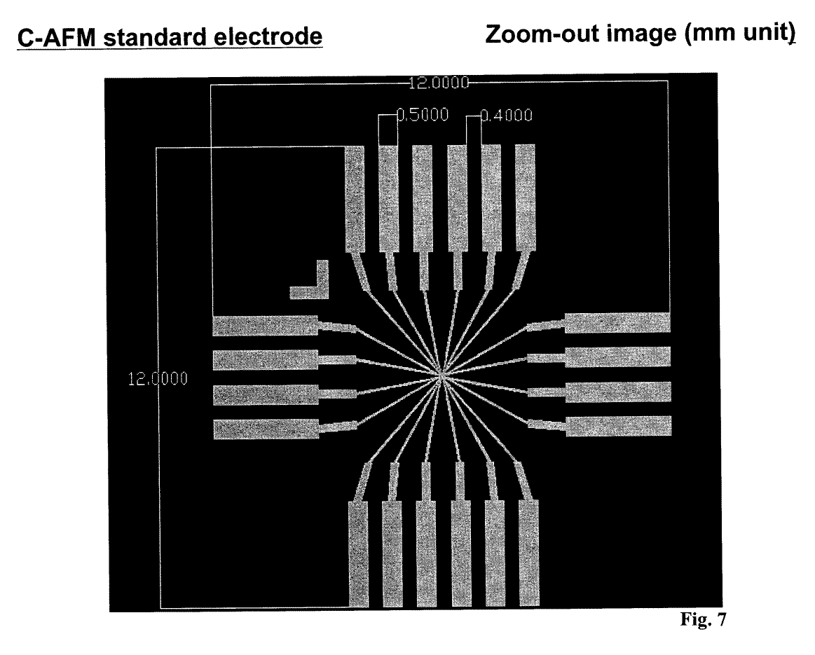

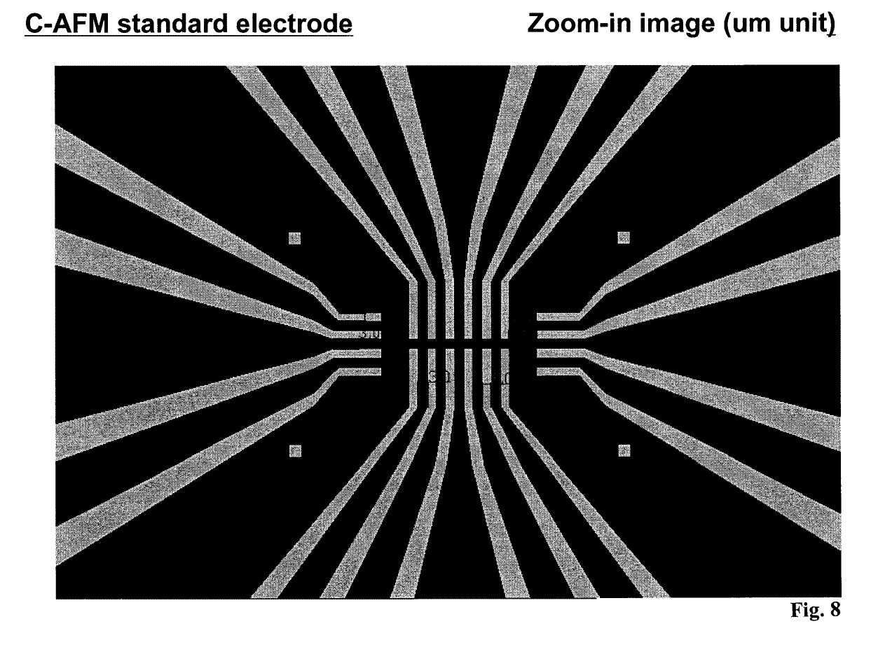

Examples of substrates were Si (after HF cleaned), SiO₂ (c-AFM) surface, and Kapton tape. The c-AFM substrate was a series of 25 nm high gold electrode on a silicon dioxide surface (see FIGS. 7 and 8).

Annealing Conditions were 150° C. for 20 minutes in an open hood or under ambient conditions.

The lines were characterized by SEM and AFM to ensure the lines were continuous. For electrical measurements, lines were written on c-AFM substrate with gold electrodes. I-V curves were generated with use of an Agilent 4156c system and two point probes. Eleven samples were prepared for measurement. Voltage was applied from −3V to 3V on one probe while the other probe was grounded. Current was generated and the average resistivity of the silver line was about 11×10⁻⁶ ohm-cm. This compared favorably with bulk resistivity reported by ink manufacturer 6×10⁻⁶ ohm-cm.

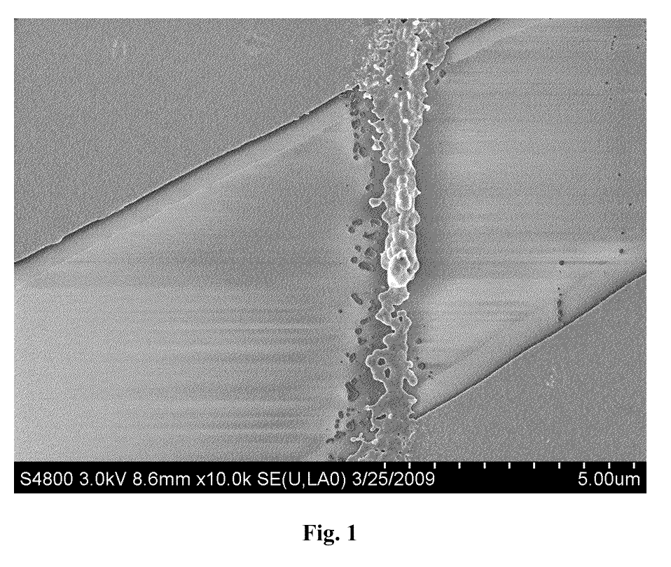

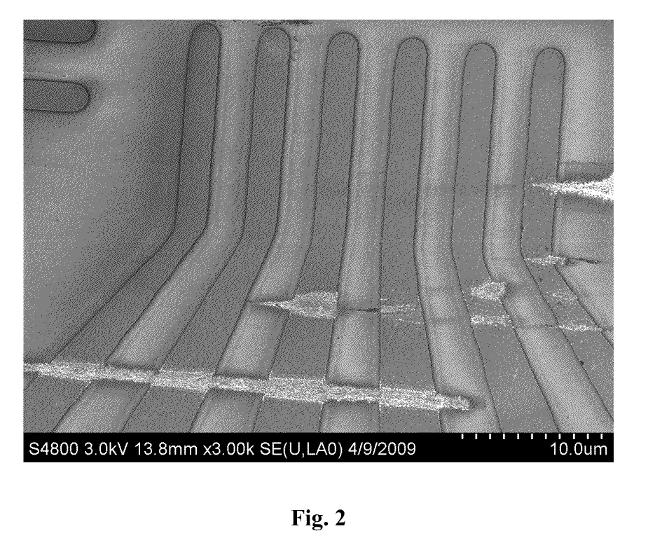

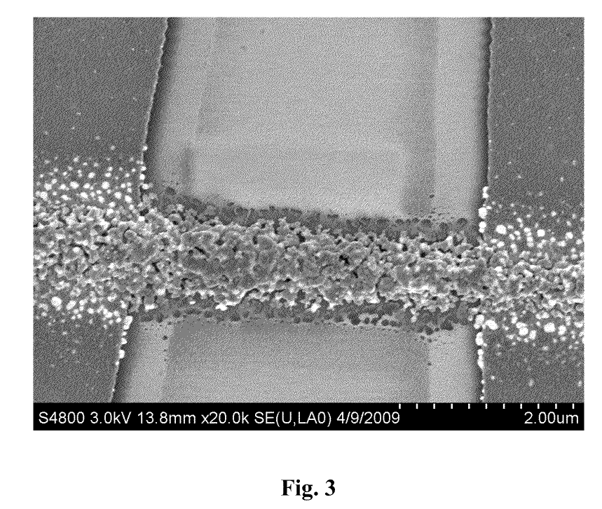

FIGS. 1-3 shows SEM images of silver lines drawn on and next to gold electrodes. FIG. 1 shows that the line width of the silver nanoparticle line is 0.6 microns and the length is six microns. Successful writing was carried out on SiOₓ (c-AFM) substrate across two gold electrodes. FIG. 2 shows line width of the silver nanoparticle line is 0.5 microns and the length is 45 microns. Successful writing was carried out on SiOₓ (c-AFM) substrate across four gold electrodes. The resistivity of the silver line was 1.1×10⁻⁵ ohm-cm. FIG. 3 shows the line width of the silver nanoparticle line was 0.5 microns and a length of 4.5 microns (c-AFM substrate).

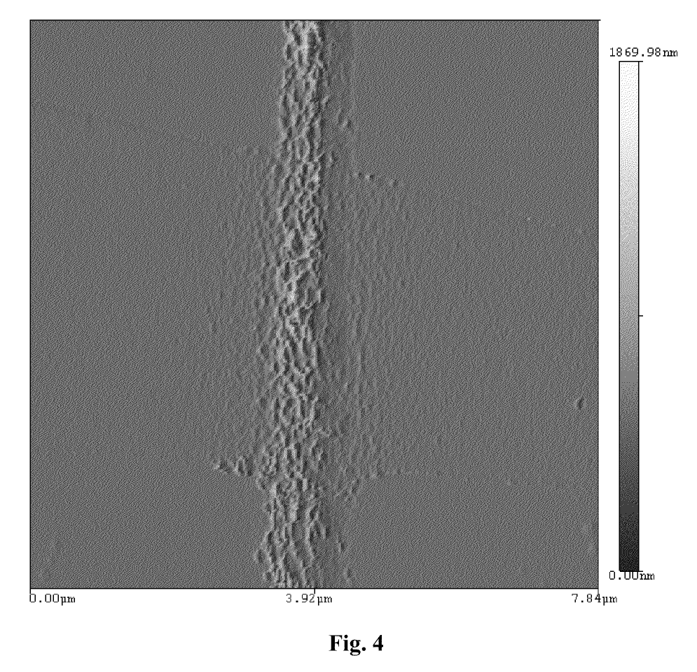

FIG. 4 shows AFM analysis of silver nanoparticle line drawn on and next to gold electrodes.

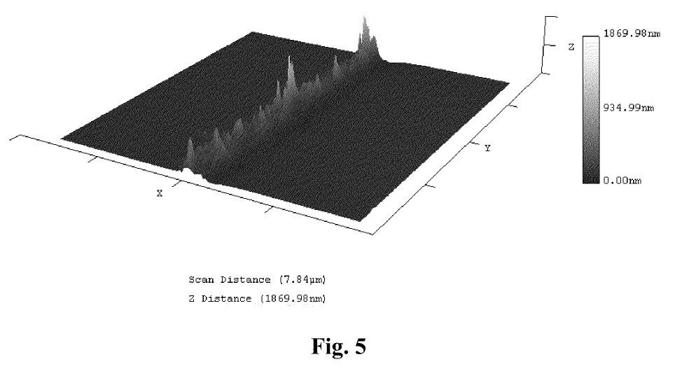

FIG. 5 shows AFM height analysis of silver nanoparticle line drawn on and next to gold electrodes.

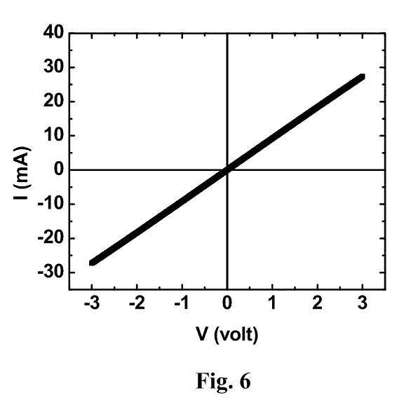

FIG. 6 shows the results of I-V testing.

FIGS. 7 and 8 show the c-AFM substrate.

### Comparative Examples

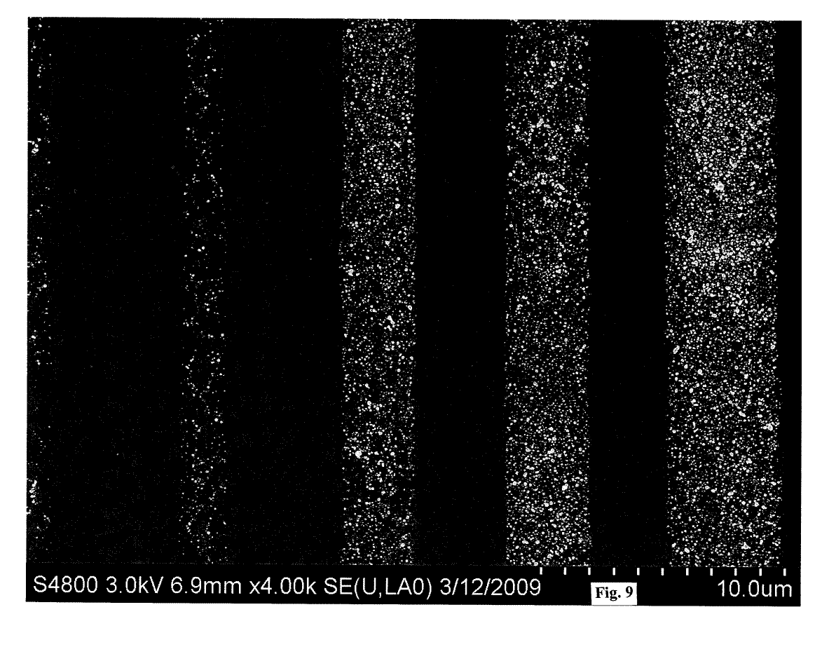

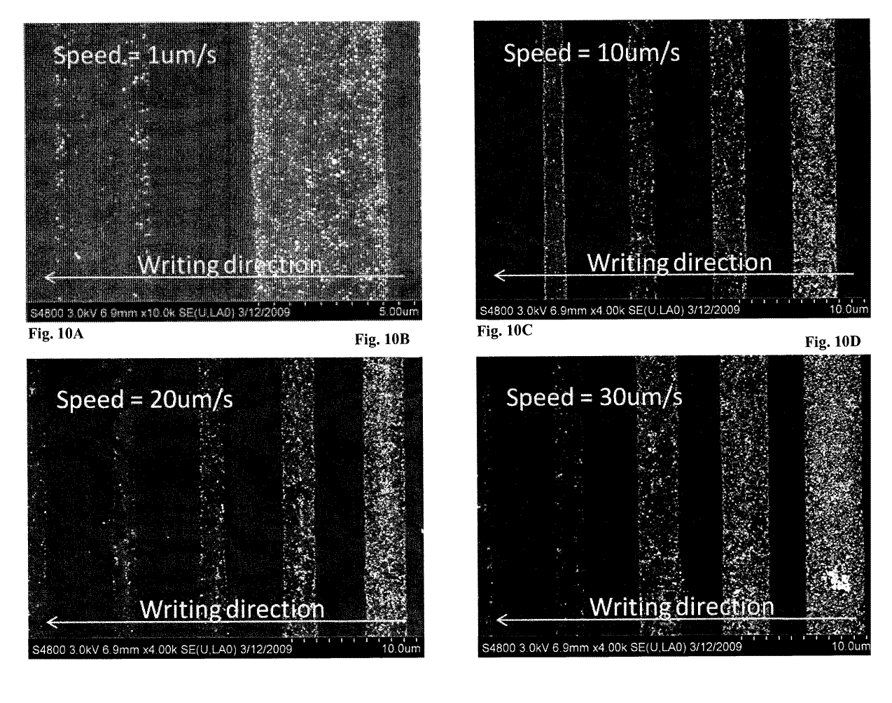

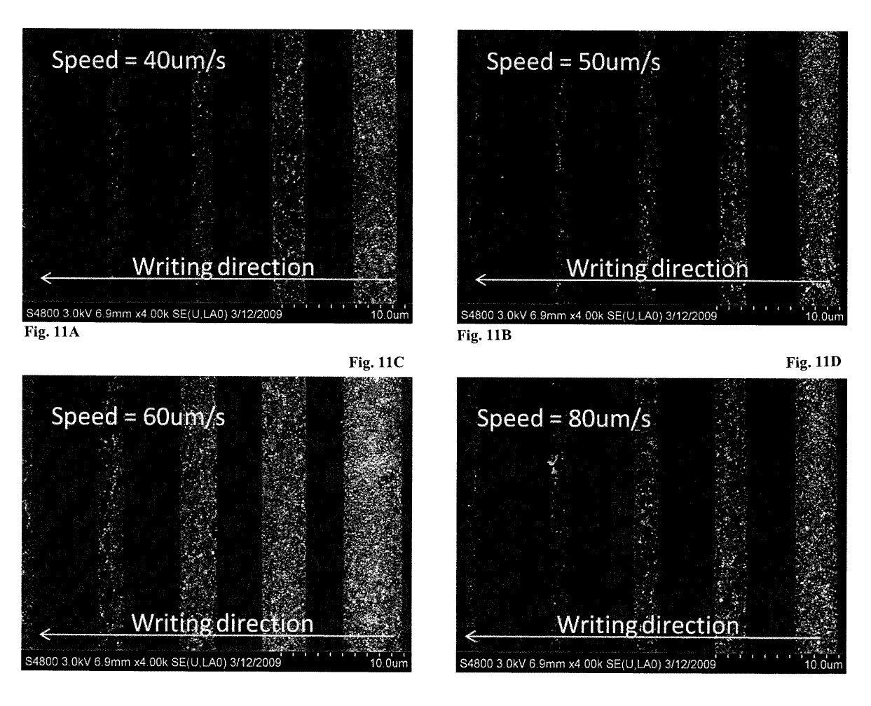

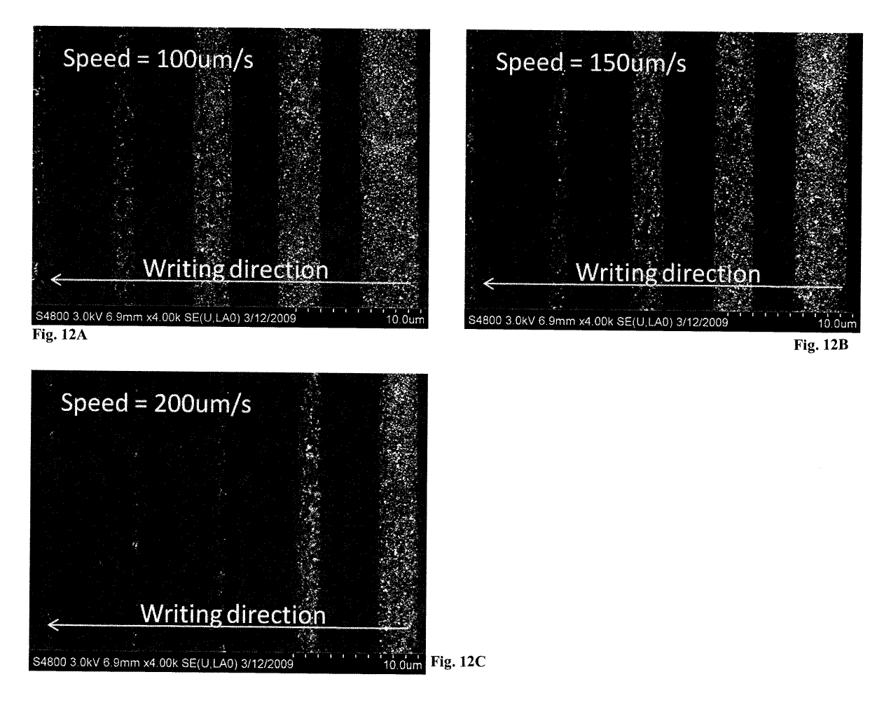

FIGS. 9-12 illustrate examples of non-continuous lines in which lower viscosity and lower metal content inks were used under a variety of writing conditions. These results are generally similar to those found in Wang et al., ACSNANO, 2, 10, 2135-2142, wherein islands of nanoparticles can be seen and continuous lines are not formed (discontinuous lines are formed). Good conductivity was not obtained.

### Working Example 2

This example describes a method of leverage DPN's unique ability to direct-write materials at specific locations to fabricate and characterize these conductive silver (Ag) line traces of measurable topography on different substrates. A silver nanoparticle (AgNP)-based ink suspension was used to pattern the sub-μm conductive traces between specific gold electrodes, and the AgMP traces were then characterized using 4-point current-voltage (I-V) measurements.

As provided below, demonstrated herein is highly repeatable dimensional control of sub-μm AgNP conductive trace patterning via DPN. This approach for creating sub-μm metallic traces is attractive since the process is highly tailorable, enables versatile pattern creation, is not substrate-specific, and does not need harsh operating conditions. Silver was chosen as the NP-based ink for a number of qualities: low bulk resistivity (˜1.6 μΩ-cm), defined applications as a plasmonic material,^{3a-c} potential applications in polyanilline based composite materials,^{3d} and material acceptance in semiconductor fabrication facilities (as opposed to gold, which can contaminate many processes). Silver has also been used to rapidly detect escherichia coli,^{3e} and has been shown to improve gas sensing characteristics of perovskite.^{3f} Additionally, a number of fundamental studies have specifically characterized the conductivities of various AgNP inks, investigated the effect of thermal curing on their electrical performance, quantified the effect of surfactant addition on the morphology of the AgNPs, and shown reversible size-tuning of AgNPs.^{4a-e}

Concurrently, DPN has been shown to pattern a wide variety of inks on a wide variety of substrates, and thorough reviews of DPN exist in recent literature.^{5a-b} In this example, previous work⁶ was improved to demonstrate sub-μm sub-50-μΩ-cm AgNP traces patterned with statistically robust line profile control down to 500 nm. The AgNP line traces were shown to form ohmic contacts with excellent electrical conductivity (28.80 μΩ-cm average resistivity as measured across 11 separate samples), and patterning versatility was highlighted by printing AgNP traces on both Kapton and mica. A commercially available AgNP-based ink (InkTec, South Korea) was direct-written using both NanoInk's NSCRIPTOR™ and DPN5000™ systems (Skokie, Ill.). Patterning was conducted without any modification to the substrate.

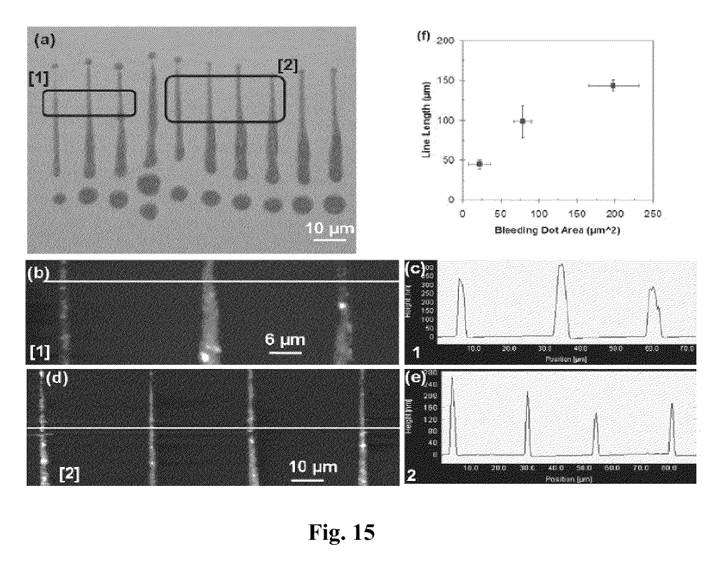

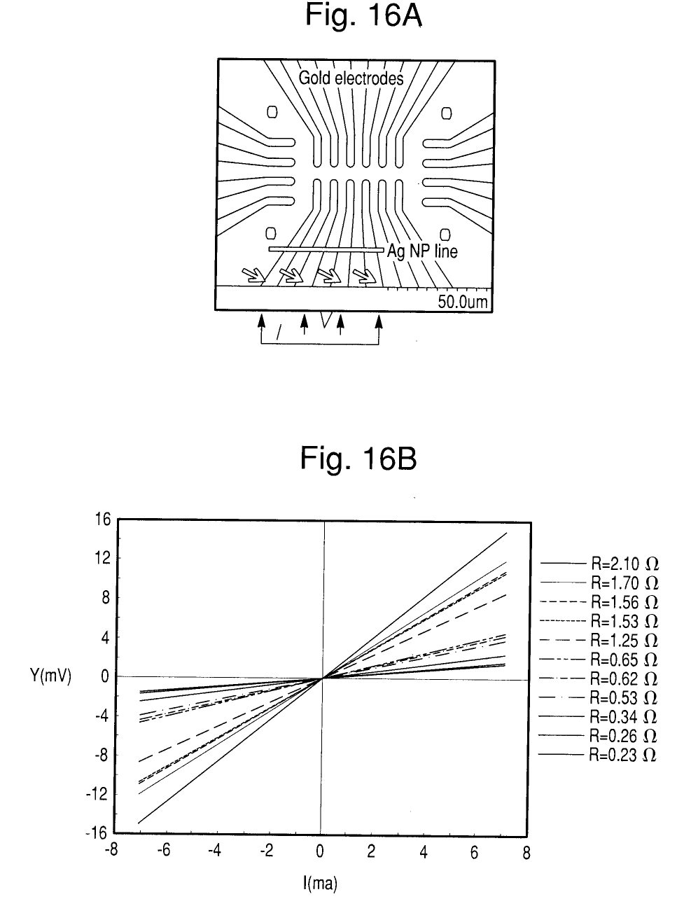

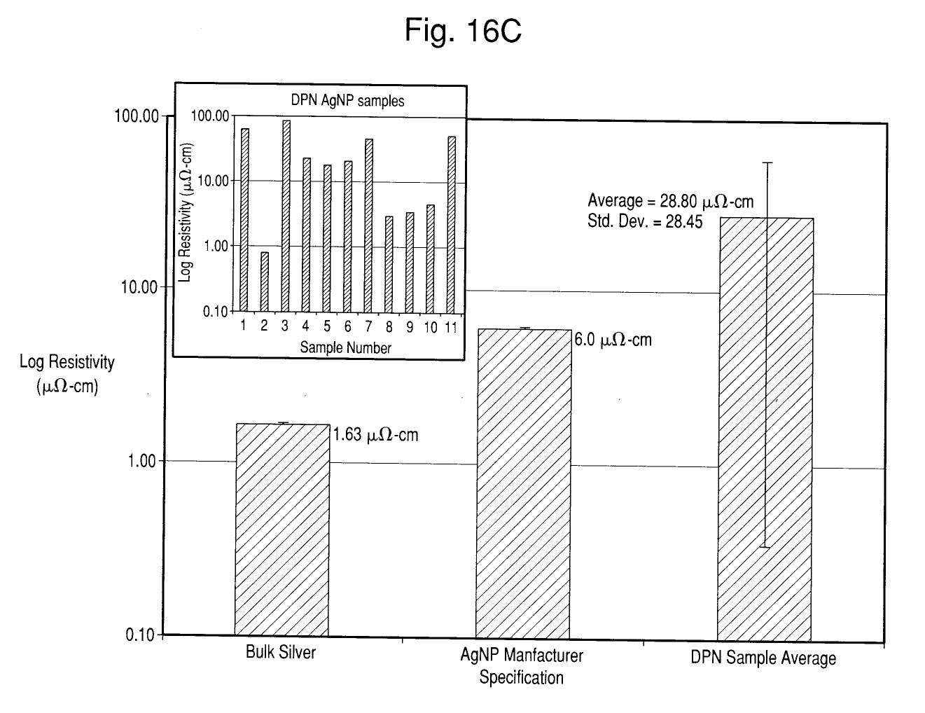

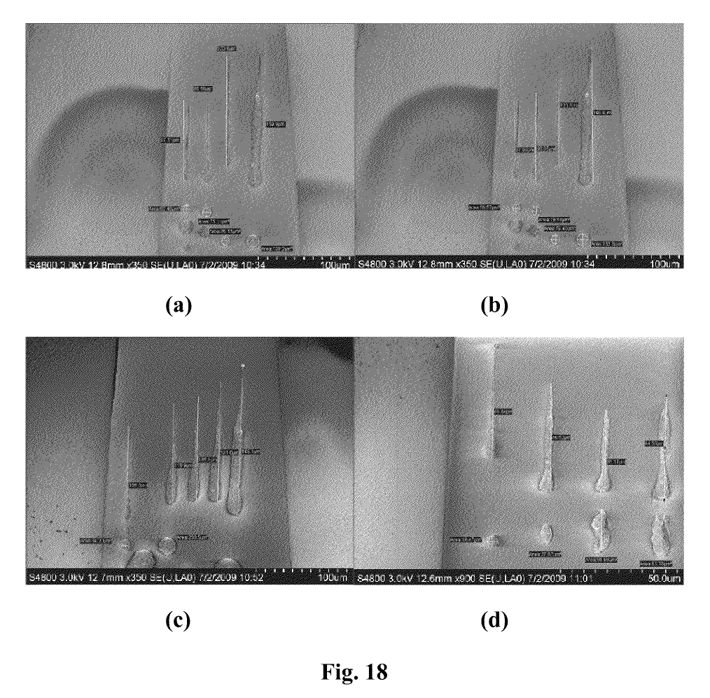

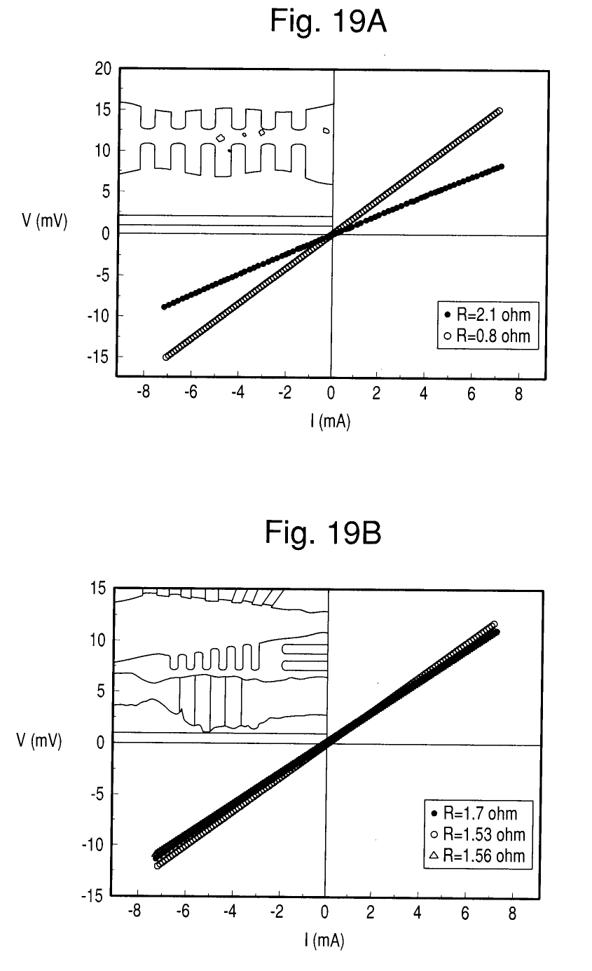

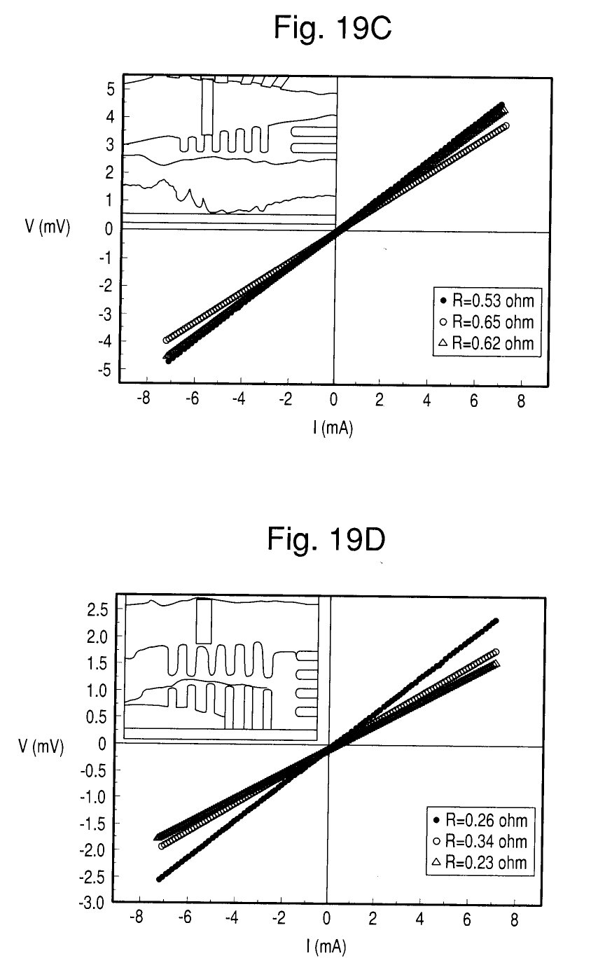

The process of site-specific AgNP conductive trace writing on a substrate is shown in FIGS. 18 and 19. Specifically, FIG. 18 shows SEM images of representative AgNP traces within electrode gaps, consisting of intentionally varied bleeding dot areas and line lengths in order to examine the relationship seen in FIG. 15(f); dot and line measurements are shown inset, and were subsequently incorporated into the plot shown in FIG. 15(f). FIG. 19 shows combined SEM images and 1-V curves showing the measurements on the multiple samples whose combined plots are shown in FIGS. 16(b) and 16(c).

Substrates: One goal of this work was to write conductive traces with minimum modification of the surface in order to reflect the real-world application of direct-writing onto specific features of a chemically/physically sensitive microelectronic device. In-house-produced gold electrodes patterned on SiO₂ (C-AFM substrates), silicon alone, Kapton, and mica substrates were used throughout this study. The Au-on-SiO₂ electrode step height was measured to be ˜25 nm. The C-AFM substrates were cleaned by sonicating in acetone and isopropyl alcohol for 5 minutes each. The substrates were subsequently rinsed with DI-water and dried with N₂. Prior to patterning, the C-AFM substrates were oxygen plasma cleaned for 3 minutes to remove organic contamination. For Si-only substrates, RCA (SC1) cleaning was also used; these were used in the process of testing and validating AgNP inks The Kapton substrates were rinsed with DI-water in order to remove surface contamination, and then dried with N₂. The mica substrates were freshly cleaved prior to DPN patterning.

Inks: A commercially available hydrophilic AgNP ink (TEC-PA-010, InkTec, South Korea) was used as the AgNP source in this study. This ink was chosen because of its high AgNP concentration. For uniform suspension, the AgNP solution was vortexed for 30 minutes prior to patterning in order to avoid phase separation. A “pre-bake” on the ink solution was also performed prior to patterning in order to modify its viscosity and make it suitable for DPN printing. (Pre-bake conditions for C-AFM substrate patterning were 60° C. for 7 minutes on a hotplate.)

DPN Patterning—Probes and Instrumentation: The silicon nitride (Si₃N₄) probes (NanoInk, types A, E, and F) were oxygen plasma cleaned for 20 seconds in order to remove organic contamination prior to inking The tips were then coated with the AgNP ink by directly dipping into a micro-pipette-deposited droplet on an SiO₂ surface, coordinated via the X-Y-Z stage motors of the patterning tools (NSCRIPTOR and DPN5000 systems, NanoInk, Skokie, Ill.). An indicative color change was observed on the cantilever as soon as it contacted the ink solution. These same motors then moved the tip to approach the patterning substrate; as the cantilever came within ˜20 μm of the substrate, the Z-piezo was successively actuated in small increments to move the tip down towards the surface. The patterning process begins with this initial, precisely calibrated touch down: excess AgNP ink was removed by creating a “bleeding dot” on first contact and then immediately retracting using the Z-piezo. Carefully monitoring these bleeding dots was found to be important to writing AgNP patterns of uniform line widths.

After initial touch down, and depending on the amount of ink loading on the tip/cantilever, the bleeding dot from a given tip can approach and then maintain a consistent size. In this example, at that point line patterning was then initiated on the given substrate, and/or across the given electrodes, using the same manual Z-piezo actuation. Force feedback was not needed for several reasons: this type of physisorbed DPN patterning is mostly force-independent, and the Z-distance needed to break contact from the AgNP ink meniscus is larger than the Z-range typically available during force feedback. Additionally, the large-range stage motors were enabled to move the sample under the tip for creating lines longer than the 90 μm limit of the piezo scanner. Following DPN patterning, the substrate was baked at 150° C. on a hotplate for 10 minutes to cure the AgNP solution and remove any excess solvent. The lateral dimensions and topography of the resulting Ag traces were evaluated via both alternating contact (tapping mode) atomic force microscope imaging (TM-AFM, scan rate ˜1 Hz) using the AFM modes of both the NSCRIPTOR and DPN5000 (NanoInk, Skokie, Ill.), and scanning electron microscopy (SEM, Hitachi S4800).

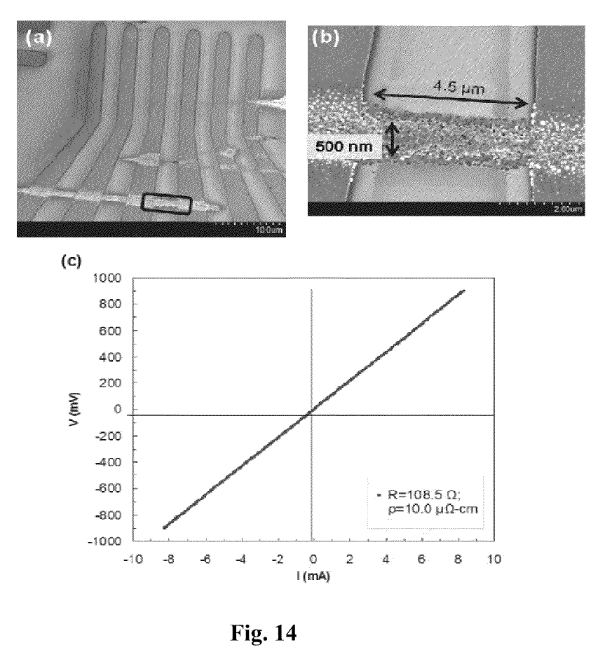

Electrical Measurements: To fabricate patterns amenable to electrical characterization, continuous AgNP traces were DPN-patterned across at least four gold electrodes on the C-AFM substrate. To circumvent the contact resistance between the probe and electrode, the current-voltage characteristics of the traces were measured with a 4-point probe system comprising a Keithley 2400 sourcemeter, an optical microscope, and four micropositioner-mounted needle probes. Example probe positions are shown in FIG. 16(a). Typically, when the thickness t_{w}, of a silicon wafer is much less than the diameter of the wafer die (i.e., t_{w}<<d_{w}), the sheet resistivity is calculated according to:

$${ρ}_{sheet} = \frac{V}{I} \cdot {t}_{w} \cdot CF ( Ω \cdot cm )$$

where the correction factor (CF) equals π/ln(2) if the distance between the probes dp is much less than the diameter of the wafer d_{w} (i.e., dₚ<<d_{w}). The resistivity of the AgNP trace is calculated according to:

$${ρ}_{trace} = \frac{R \cdot A}{1} = \frac{V}{1} \cdot \frac{A}{1} = \frac{V \cdot h \cdot w}{1 \cdot 1} ( Ω \cdot cm )$$

where h and w are the respective topographic height and line width of the AgNP trace (as measured by TM-AFM). The average AgNP trace height h was measured to be ˜500 nm, with an example 500 nm line width w across an electrode shown in FIG. 14(b). The trace lengths (I) were measured via SEM, and simultaneously corroborated the measured line widths (w). Based on these parameters, I-V curve data were obtained for 11 individual AgNP traces (FIG. 16(b)), and calculated an average resistivity of 28.80 μΩ-cm (FIG. 16(c)). By comparison, bulk Ag resistivity is 1.63 μΩ-cm and the AgNP ink manufacturer's specification is “<6.0 μΩ-cm.” This variation was within tolerance given that AgNP resistivity has been shown to vary from <5 μΩ-cm up to 20 μΩ-cm based on differences in the thermal baking process.^{3a-b}

Conductive AgNP traces were created by moving inked silicon nitride (SiN) probes across SiO₂ substrates at a specific tip speed (a schematic depiction is shown in FIG. 13(b)). Due to the viscosity of this AgNP ink solution, a tip speed was characterized for its “sweet spot” range, in which ink transport to the surface proceeded optimally; note that this range—1400-1600 μm/s—is nearly four orders of magnitude higher than typical thiol-on-gold DPN tip speeds (0.5-5.0 μm/s),^{2a} lending further credence to this ink system's versatility and applicability as a rapid prototyping technique. The kinetics of ink flow from the inked AgNP tip to the substrate (depicted in FIG. 13(a)) are controlled by surface tension and ink viscosity. AgNP ink organization and orientation on the surface, however, is substantially a physisorption-driven phenomena, as the AgNP experiences very limited affinity toward the surface due to the solvent suspending the nanoparticles. This turns out to be a benefit for this ink system as it makes it more widely applicable to a variety of substrates. Since these physisorbed inks tend to be more substrate-general, demonstrated herein is the versatility of this conductive trace printing across multiple substrates (SiO₂, Si, mica, and Kapton).

It is noted that because this AgNP ink is already in the liquid phase, the transport process does not seem to rely on a water meniscus, and experimental parameters of temperature and relative humidity had virtually no effect on the viscous paste meniscus or the resulting patterns. In the end, proper tuning of ink viscosity, AgNP concentration, and AgNP suspension during DPN can be important factors leading to continuous and conductive silver traces; sub-optimal AgNP concentration or suspension can lead to either discontinuous traces or lack of ink transport from the tip during DPN.

Scanning Electron Microscopy (SEM) images of conductive silver traces are seen in FIG. 14(a)-(b). The overall electrode configuration shown in FIG. 14(a) yields many potential patterning sites; FIG. 14(b) shows an SEM close-up of a conductive 500 nm wide silver trace spanning the 4.5 μm gap between the gold electrodes. Notably, the trace had no difficulty maintaining continuity up and over the ˜25 nm electrode step height. The I-V behavior of this continuous trace is seen in FIG. 14(c)—the trace is highly conductive, with a resistance R=108.5Ω and a corresponding resistivity p=10.0 μΩ-cm. Considering that bulk silver p=1.63μΩ-cm, this is an encouraging result: the sub-gm scale of our trace would alone suggest slightly different electrical performance compared to bulk. Furthermore, conductive inks for DOD ink jet printing have widely varying manufactured specifications, and their resulting resistivities have been shown to vary substantially (from <5 to 20 μΩ-cm) based on annealing conditions.^{3a-b} At the sub-μm scale in the presently described example, the expected range of electrical behavior was observed, with the additional benefits of a direct-write methodology.

A goal of this example was not only to demonstrate the electrical behavior of one sub-μm trace but also to validate the robustness of the methodology. To that end, FIG. 15 shows repeatable deposition and subsequent characterization. 10 separate SiN probes were prepared, inked nominally identically but at different times, and, using the patterning methods described herein, 10 continuous adjacent traces were generated on the same SiO₂ substrate (FIG. 15(a)). This shows that by monitoring the initial bleeding dot behavior, it is straightforward to produce continuous traces of consistent line profiles. At a predefined tip speed of 1500 μm/s, the feature width is controlled by the dynamic depletion of viscous AgNP ink from the tip and cantilever. Writing from thick to thin, the traces become reliably sub-gm in their top half (shown in FIGS. 15(b) and 15(d)), with overall line lengths consistently more than 100 μm. (Note microcircuit electrode gaps are often ˜40 μm.)

These probes were independently verified to continue writing with similar behavior after being re-dipped. All of the traces show appreciable height (FIGS. 15(c) and 15(e)), and these data were incorporated for subsequent resistivity calculations. Moreover, the data reveal a roughly linear relationship between initial bleeding dot area and resulting line length (FIG. 15(f)). Thus, by monitoring the initial bleeding dot size, one can not only ensure a consistent line profile, but also tailor its overall size and length.

Also demonstrated was the electrical reliability of the AgNP DPN methodology. FIG. 16(a) shows an SEM image of an unpatterned C-AFM substrate with a schematic line indicating a typical location of a DPN-patterned AgNP conductive trace, along with arrow indications for placing the 4-point probe measurement needles. FIG. 16(b) shows I-V curve data generated from 11 separate sets of electrodes, covering a range of resistances from R=0.23-2.10Ω. A range of corresponding resistivities were derived, as described above, to be from ρ=0.8-86.0 μΩ-cm (plotted in FIG. 16(c) inset). Further, FIG. 16(c) shows the average of 28.80±28.45 μΩ-cm which compares favorably with the ink manufacturer's specification of 6.0μΩ-cm, and bulk silver ρ=1.63 μΩ-cm. In conjunction with the data from FIG. 15 FIG. 16(a)-(c) show a robust method to generate consistent, continuous, and sub-50-μΩ-cm conductive traces.

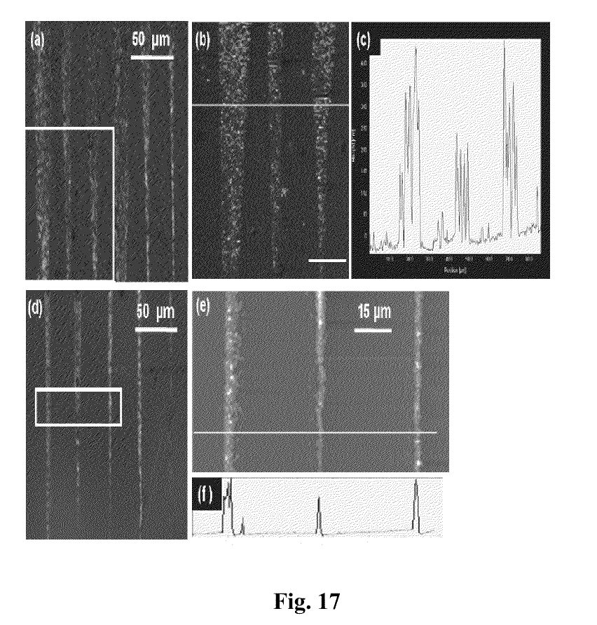

Finally, to demonstrate the versatility and applicability of this methodology, continuous traces were printed on both Kapton tape and mica. FIGS. 17(a) and 17(d) show optical images of the traces after curing, with corresponding TM-AFM height images seen in FIGS. 17(b) and 17(e). FIGS. 17(c) and 17(f) show that, despite being on different substrates, this AgNP ink formed continuous traces with line widths and heights commensurate with the previous SiO₂ traces.

A reliable method has been demonstrated to directly deposit conductive silver traces using DPN, an approach that is useful for a diverse collection of applications from gas sensing to circuit element failure analysis. DPN provides a new solution both for creating a conductive trace between two specific electrodes, and for sub-μm decoration of existing microstructures with conductive material. This present methodology provided statistically robust documentation of dimensional pattern control (down to 500 nm) and electrical performance (28.80 μΩ-cm average). The versatility of this method was also shown on additional substrates (Kapton, mica).

### REFERENCES

[1] a) Burns et al., MRS Bull. 2003, 28, 829.
   b) Perelaer et al., Adv. Mater. 2006, 18, 2101.
   c) Li et al., Adv. Mater. 2003, 15, 1639.
   d) Ahn et al., Science 2009, 323, 1590.
   e) Cao et al., Small. 2009, 5, 1144.
   f) Stellacci et al., Adv. Mater. 2002, 14, 194.
   g) Ishikawa et al., Appl. Phys. Lett. 2006, 89, Art. No. 113102.
   h) Park et al., Small 2009, 5, 134.
   i) Wu et al, Thin Solid Films 2009, 517, 5913.
   j) Kim, et al. Jap. J. Appl. Phys. 2009, 48, 06FD14.
   k) Choi, et al., Lee, Jap. J. Appl. Phys. 2009, 48, 06FH02.
   l) Santhanam, et al., Nano Lett. 2004, 4, 41.
   m) Wang, et al., Direct Patterning of Gold Nanoparticles Using Dip-Pen Nanolithography, ACS Nano 2008, 2, 2135.
[2] a) Haaheim, Ultramicroscopy 2005, 103, 117.
   b) Nafday, et al., Scanning 2009, 31, 122.
[3] a) Murray, et al., Adv. Mater. 2007, 19, 3771.
   b) Yeshchenko, et al, Physical Rev. B 2009, 79, Art. No. 235438.
   c) Tai, et al., Adv. Mater. 2007, 19, 4520.
   d) Choudhary, Sens. Actuators B: Chem 2009, 138, 318.
   e) Kalele, et al., Small 2006, 2, 335.
   f) Michel, et al., Mat. Sci. Eng B. 2007, 141, 1.
[4] a) Park, et al., Coll. Surf A 2008, 313-314, 351.
   b) Greer, et al., Acta Mater. 2007, 55, 6345.
   c) Park, et al., Solid State Phenomena 2007, 124-126, 1205.
   d) Oh, et al., Small 2009, 5, 1311.
   e) Fuertes, et al., Small 2009, 2, 272.
[5] a) Salaita, et al., Nat. Nanotech. 2007, 2, 145.
   b) Haaheim, et al., Scanning 2008, 30, 137.
[6] Wang, et al., Appl. Phys. Lett. 2008, 93, Art. No. 143105.

What is claimed:

1. A method comprising:
providing at least one tip,
providing at least one substrate,
disposing at least one nanoparticle ink on the tip, wherein the ink comprises at least metallic nanoparticles and at least one solvent carrier and has a viscosity of at least 2,500 cps,
moving the tip and substrate closer to each other such that at least some of the nanoparticle ink is deposited from the tip to the substrate.

2. The method of claim 1, wherein the ink has a viscosity of at least 5,000 cps.

3. The method of claim 1, wherein the ink has a viscosity of at least 6,000 cps.

4. The method of claim 1, wherein the ink has a viscosity of at least 7,000 cps.

5. The method of claim 1, wherein the metallic nanoparticles are silver nanoparticles.

6. The method of claim 1, wherein the ink has a density of at least 2 g/cc.

7. The method of claim 1, wherein the ink has a metal content of more than 40% by weight.

8. The method of claim 1, wherein the ink has a metal content of at least 45% by wt.

9. The method of claim 1, wherein the ink has a metal content of at least 55% by wt.

10. The method of claim 1, wherein the ink has a viscosity of at least 2,500 cps, a density of at least 2 g/cc, and a metal content of at least 45% by wt.

11. The method of claim 1, wherein nanoparticles comprise silver nanoparticles, and the ink is a paste and has a viscosity of at least 5,000 cps, a density of at least 2 g/cc, and a metal content of at least 45% by wt.

12. The method of claim 1, further comprising the step of moving the tip along the substrate to form a line, wherein the line is at least 40 microns long.

13. The method of claim 1, further comprising the step of moving the tip along the substrate to form a line, wherein the line has a line width of less than about one micron.

14. The method of claim 1, further comprising the step of moving the tip along the substrate to form a line and annealing the line at a temperature of about 100° C. to about 200° C.

15. The method of claim 1, further comprising the step of moving the tip along the substrate to form a line and annealing the line at a temperature of about 120° C. to about 170° C.

16. The method of claim 1, further comprising the step of moving the tip along the substrate to form a line and annealing the line to form a conductive line having a resistivity of less than 2×10⁻⁵ ohm-cm.

17. The method of claim 1, further comprising the step of moving the tip along the substrate to form a line and annealing the line to form a conductive line having a resistivity of less than 1.1×10⁻⁵ ohm-cm.

18. The method of claim 1, wherein the ink is substantially or totally free of glycerol.

19. The method of claim 1, wherein the ink is not a reactive ink.

20. The method of claim 1, wherein the tip is a nanoscopic tip.

21. The method of claim 1, wherein the tip is a scanning probe microscope tip or an AFM tip.

22. The method of claim 1, wherein the tip is a polymeric tip.

23. The method of claim 1, wherein the tip is a solid tip.

24. The method of claim 1, wherein the tip is a hollow tip.

25. The method of claim 1, wherein the tip is a hydrophilic tip.

26. The method of claim 1, further comprising the step of moving the tip along the substrate at a rate of about 1 micron/second to about 100 microns/second.

27. The method of claim 1, further comprising the step of moving the tip along the substrate at a rate of about 40 microns/s to about 80 microns/s.

28. The method of claim 1, wherein deposition occurs in a controlled environment to minimize evaporation of ink solvent.

29. The method of claim 1, wherein the substrate comprises silicon, silicon oxide, polyimide, ITO, or mica.

30. The method of claim 1, wherein the substrate comprises a plurality of conductive lines and the deposition provides electrical conductivity between at least two of the lines.

31. A method comprising:
providing at least one tip or stamp,
providing at least one substrate,
disposing at least one nanoparticle ink on the tip or stamp, wherein the ink comprises a paste comprising at least metallic nanoparticles and at least one solvent carrier,
moving the tip or stamp and the substrate closer to each other such that at least some of the nanoparticle ink is deposited from the tip or stamp to the substrate.

32. The method of claim 31, wherein the stamp is a polymer stamp.

33. The method of claim 31, wherein the stamp is an elastomeric stamp.

34. The method of claim 31, wherein the stamp is a silicone stamp.

35. The method of claim 31, wherein the stamp is a microcontact printing stamp.

36. The method of claim 31, wherein the stamp is hydrophilically treated.

37. The method of claim 31, wherein the stamp comprises nanopatterns.

38. The method of claim 31, wherein the stamp comprises at least one line pattern.

39. The method of claim 31, wherein the stamp is used rather than the tip, and the ink is adapted for use with the stamp.

40. The method of claim 31, wherein the tip is used rather than the stamp, and the ink is adapted for use with the tip.

41. A method comprising:
providing at least one tip,
providing at least one substrate,
disposing at least one nanoparticle ink on the tip,
moving the tip and substrate closer to each other such that at least some of the nanoparticle ink is deposited from the tip to the substrate, wherein the ink is formulated to provide after annealing a continuous line with resistivity of less than about 1.1×10⁻⁵ ohm-cm.

42. The method of claim 41, wherein the ink is formulated for viscosity control.

43. The method of claim 41, wherein the ink is formulated for density control.

44. The method of claim 41, wherein the ink is formulated for metal content control.

45. The method of claim 41, wherein the ink is formulated to not comprise glycerol.

46. The method of claim 41, wherein the annealing is carried out at a temperature of less than 200° C.

47. The method of claim 41, wherein the annealing is carried out for a time less than thirty minutes.

48. The method of claim 41, wherein the annealing is carried out at a temperature of about 100° C. to about 150° C.

49. The method of claim 41, wherein the line is at least five microns long.

50. The method of claim 41, wherein the line is at least 40 microns long.

51. A method comprising:
providing at least one substrate,
directly writing at least one nanoparticle ink on the substrate, wherein the ink is formulated to provide after annealing continuous lines with resistivity of less than about 1.1×10⁻⁵ ohm-cm.

52. The method of claim 51, wherein the method comprises use of a tip or stamp to transfer the nanoparticle ink to the substrate.

53. The method of claim 51, wherein the viscosity of the ink is at least 2,500 cps.

54. A method comprising:
providing at least one tip,
providing at least one substrate,
disposing at least one nanoparticle ink on the tip, wherein the ink comprises at least metallic nanoparticles and at least one solvent carrier and has content of nanoparticles of at least 45% by weight,
moving the tip and substrate closer to each other such that at least some of the nanoparticle ink is deposited from the tip to the substrate.

55. A method comprising drawing a continuous metallic line with an aspect ratio of at least 25 from an ink composition comprising metallic nanoparticles, wherein the line upon annealing shows a resistivity of less than about 1.1×10⁻⁵ ohm-cm.

56. The method of claim 55, wherein the line is deposited next to another feature, wherein the feature and the line are separated by a spacing, and the spacing is less than about five microns.

57. The method of claim 55, wherein the line is deposited next to another feature, wherein the feature and the line are separated by a spacing, and the spacing is less than about one micron.

58. The method of claim 55, wherein the line is deposited next to another feature, wherein the feature and the line are separated by a spacing, and the spacing is less than about 500 nm.

59. The method of claim 55, wherein the line is deposited next to another feature, wherein the feature and the line are separated by a spacing, and the spacing is less than about 250 nm.

60. The method of claim 55, wherein the line is deposited over another feature.

61. An article prepared by methods comprising the method of claim 1.

62. The article of claim 61, wherein the article is an electrode device.

63. The article of claim 61, wherein the article is an electronic device.

64. A method comprising:
(i) providing a tip with a nanoparticle ink disposed thereon;
(ii) moving the tip closer to a first location on a substrate such that at least some of the ink composition is deposited from the tip to the first location on the substrate;
(iii) moving the tip away from the substrate; and
(iv) moving the tip closer to a second location on the substrate such that at least some of the remaining ink is deposited from the tip to the second location on the substrate to form a pattern.

65. The method of claim 64, further comprising repeating steps (ii) and (iii) before step (iv).

66. The method of claim 64, further comprising disposing the ink onto the tip.

67. The method of claim 66, further comprising cleaning the tip before disposing the ink thereon.

68. The method of claim 66, further comprising prebaking the ink composition before disposing the ink onto the tip.

69. The method of claim 66, further comprising prebaking the ink composition on a heated tip before disposing the ink onto the tipi.

70. The method of claim 64, wherein steps (iii)-(iv) are carried out with a z-piezo control actuator.

71. The method of claim 64, wherein step (iv) is carried out without substantially forming a water meniscus.

72. A method comprising:
(i) providing at least a first and a second electrode; and
(ii) depositing at least one nanoparticle ink from a tip onto a first portion of the first and a second portion of the second electrodes so as to provide after annealing the ink a continuous line in electrical contact with both the first and second portion.

73. The method of claim 72, wherein the line upon annealing has a resistivity of less than about 1.1×10⁻⁵ ohm-cm.

74. The method of claim 72, wherein the line upon annealing has a width less than 1 micron.

75. The method of claim 72, wherein the tip is a polymeric tip.

76. An article, comprising a continuous line comprising annealed nanoparticles, wherein the line has a resistivity of less than about 1.1×10⁻⁵ ohm-cm and a width of less than 1 micron.

77. The article of claim 76, wherein the line has a resistivity of less than 50×10⁻⁶ ohm-cm.

78. The article of claim 76, wherein the line is generated by dip-pen nanolithography.

79. The article of claim 76, wherein the nanoparticle comprises silver.
